(19) United States
(12) Patent Application Publication
(10) Pub. No.: US 2026/0251608 A1
(43) Pub. Date: Aug. 27, 2026

(54) ELECTROCHEMICAL BIOSENSORS AND METHOD OF PREPARING ELECTROCHEMICAL BIOSENSORS

(71) Applicant: GLC MEDICAL (GLCM) INC., Edmonton (CA)

(72) Inventors: Ushula TEFASHE, Edmonton (CA); Mikolai VAJDA, Edmonton (CA); Brad KRUECKL, Edmonton (CA); Josh GÉNÉREUX, Edmonton (CA)

(21) Appl. No.: 18/877,954

(22) PCT Filed: Jun. 20, 2023
(86) PCT No.: PCT/CA2023/050857

§ 371 Date: Dec. 20, 2024

Related U.S. Application Data
(60) Provisional application No. 63/353,831, filed on Jun. 20, 2022.

(51) Int. Cl. G01N 27/30; G01N 27/327

(52) U.S. Cl. CPC G01N 27/308; G01N 27/3276

(57) ABSTRACT

A biosensor is manufactured by printing electrodes on a substrate using metallic ink; printing a carbon surface using carbon-containing ink, the carbon surface being in electrical communication with the electrodes; immersing the substrate in an acid bath having a pH of less than 3.0 and applying a first voltage cycle, and immersing the substrate in a basic bath having a pH of at least 13.0. Each of the first voltage cycle and the second voltage cycle comprise a voltage that is less than 0 V and that is greater than 0 V.

### TECHNICAL FIELD

This relates to electrochemical biosensors, and in particular, electrochemical biosensors with printed metal and carbon electrodes.

### BACKGROUND

With the recent global pandemic, efforts towards the development of rapid tests for viruses and infection by-products have led to a general push to improve sensing technology for diagnostic applications. In these devices, binding events at the surface of material with targeted functionality leads to a change in a measurable physical property such as colour, fluorescence, or electrochemical signal.

### SUMMARY

According to an aspect, there is provided a method of manufacturing a biosensor, comprising the steps of: printing electrodes on a substrate using metallic ink; printing a carbon surface using carbon-containing ink, the carbon surface being in electrical communication with the electrodes; immersing the substrate in an acid bath having a pH of less than 3.0 and applying a first voltage cycle to the biosensor electrodes; from a minimum voltage of between −0.4 V and −0.2 V to a maximum voltage of between 0.8 V and 1.0 V; and immersing the substrate in a basic bath having a pH of greater than 14.0 and applying a second voltage cycle. Each of the first voltage cycle and the second voltage cycle comprise a minimum voltage that is less than 0 V and a maximum voltage that is greater than 0 V, the minimum voltage and the maximum voltage being selected to avoid damaging the electrodes and the carbon surface across a plurality of first voltage cycles and a plurality of second voltage cycles.

According to other aspects, the acidic pH may be between 1.0 to 3.0, the maximum voltage may be between 0.8 V and 1.0 V, and the minimum voltage may be between −0.4 V and −0.2 V; the basic pH may be between 13.0 and 14.0, the minimum voltage may be between −2.1 V and −1.9 V, and the maximum voltage may be between 1.4 V and 1.6 V; the first voltage cycle may be applied 50 times or more; the second voltage cycle may be applied 50 times or more; and the electrodes and the substrate may be cured by heating to a temperature of between 100-150° C. for 10 minutes or more.

According to an aspect, there is provided a method of manufacturing a biosensor, comprising: printing electrodes on a substrate using metallic ink; printing a carbon surface using carbon-containing ink, the carbon surface being in electrical communication with the electrodes; immersing the substrate in an acid bath having an acidic pH and applying a first voltage cycle to the biosensor electrodes; and immersing the substrate in a basic bath having a basic pH and applying a second voltage cycle to the biosensor electrodes; wherein the first voltage cycle relates to a potential of a redox couple in the acid bath and the second voltage cycle relates to a potential of a redox couple in the basic bath.

According to other aspects, the method may include on or more of the following aspects: the fraction of the pH in the first voltage cycle and the second voltage cycle may be about 0.0591 of the pH; the acidic pH may be between 1.0 to 3.0; the basic pH may be between 13.0 and 14.0; the first voltage cycle may be applied 50 times or more; the second voltage cycle may be applied 50 times or more; the electrodes and the substrate may be cured by heating to a temperature of between 100-150° C. for 10 minutes or more.

In other aspects, the features described above may be combined together in any reasonable combination as will be recognized by those skilled in the art.

### BRIEF DESCRIPTION OF THE DRAWINGS

These and other features will become more apparent from the following description in which reference is made to the appended drawings, the drawings are for the purposes of illustration only and are not intended to be in any way limiting, wherein:

FIG. 1 is a flowchart of the fabrication process for printing electrodes on a substrate to make a biosensor.

FIG. 2 is a flowchart showing the fabrication process and working principle of a sensor that uses electrochemical impedance spectroscopy detection.

FIG. 3 is a graph of cyclic voltammograms of a screen-printed carbon electrode cleaning process in an acidic solution.

FIG. 4 is a graph of cyclic voltammograms of a screen-printed carbon electrode cleaning process in a basic solution.

### DETAILED DESCRIPTION OF PREFERRED EMBODIMENTS

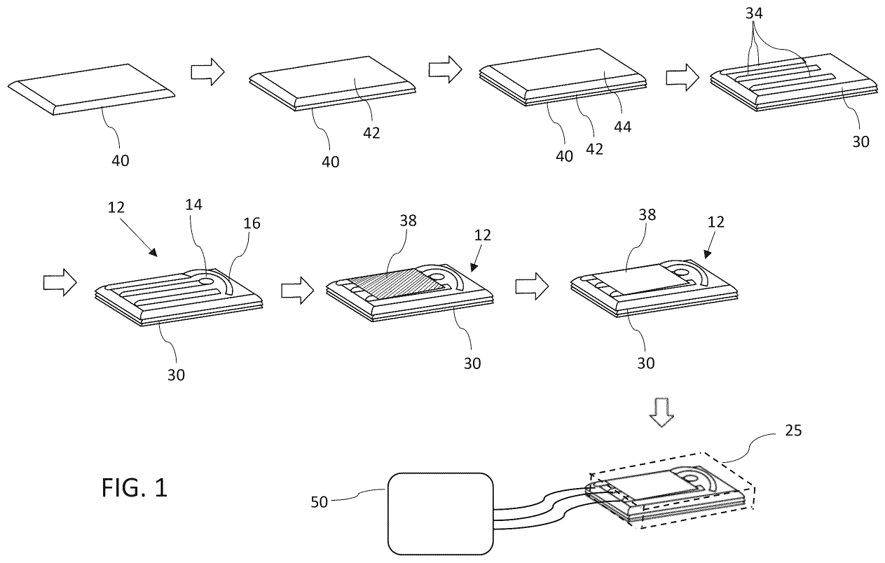

A biosensor, generally identified by reference number 10, will now be described with reference to FIG. 1 through 4. The present discussion relates to a method for preparing biosensor 10, which uses electrochemical impedance spectroscopy (EIS) and has highly reproducible electrochemical characteristics through electrochemical cleaning and functionalization of screen-printed carbon electrodes.

Referring to FIG. 1, sensor 10 supports a device architecture 12. Device architecture 12 includes a working electrode 14, a counter electrode 16, and a reference electrode 18. Working electrode 14 has a functionalized carbon surface 20, which has been functionalized to target an analyte of interest 22. The electrodes 14, 16, and 18 may be screen printed carbon, which may be produced using an ink that contains amorphous carbon, carbon black, graphite, exfoliated graphite, graphene nanoplatelets, or combinations thereof and may include binders, stabilizers, or other additives to improve the properties of the ink. The carbon ink may be primarily sp² carbon. While the use of a screen-printed carbon electrode is discussed in detail below, the carbon surface may also be generated by coating an electrode made from a different material with carbon ink, provided that the carbon surface is compatible with the functionalization chemistry described below.

The performance of the sensor depends in part on the density of the surface bound linker that tethers the biomolecule to the surface, and the amount of surface left exposed. The nature of the linker chosen depends on several factors including what the desired chemical properties of the linker are to bind it to the biological recognition element, and the ability to bind to the surface through electrografting under applied potential. Since the tethering of the biological analyte of interest to the surface is reliant only on the presence of a primary amine, the family of molecules to be used as the biological recognition element may include oligopeptides and polypeptides, including proteins, enzymes, and in some examples, antibodies, though the technology need not be limited to biomolecules. The electrode surface may be functionalized with a single biological recognition element or may be functionalized with several molecules which may be selected to target different analytes, or different regions of the same analyte.

Cyclic voltammetry (CV) is a versatile electrochemical technique, and it can be employed as a cleaning method for screen-printed electrodes in both acidic and basic media. The cleaning process involves applying a potential sweep to the electrode in the presence of a cleaning solution. The equation relating the applied voltage to the pH of the cleaning solution may depend on the redox reactions occurring during the cleaning process.

In an acidic cleaning solution, such as sulfuric acid (H₂SO₄) or hydrochloric acid (HCl), the predominant redox reaction involves the removal of organic contaminants and oxidation of any residual electroactive species on the electrode surface. The applied voltage (V) may be related to the pH (pH_{acid}) of the acidic cleaning solution by the following equation:

$$V = {E}_{acid} + a ( p {H}_{acid} )$$

where E_{acid} represents the standard potential of the redox couple involved in the cleaning process, and a is the conversion factor representing the slope of the Nernst equation at room temperature (25° C.) when considering the pH dependence. In this case, a=0.0591.

In a basic cleaning solution, such as sodium hydroxide (NaOH) or potassium hydroxide (KOH), the cleaning process primarily involves the reduction of metal oxide/hydroxide contaminants that may be present on the electrode surface. The applied voltage (V) may be related to the pH (pH_{basic}) of the basic cleaning solution by the following equation:

$$V = {E}_{basic} - a ( p {H}_{basic} )$$

where E_{basic} represents the standard potential of the redox couple involved in the cleaning process. The negative sign is used because the reduction process occurs at more negative potentials.

During the cyclic voltammetry cleaning process, a potential sweep is typically applied to the electrode from a lower potential value to a higher potential value at a predetermined scan rate. This potential range may be chosen based on the cleaning requirements and the stability limits of the electrode material.

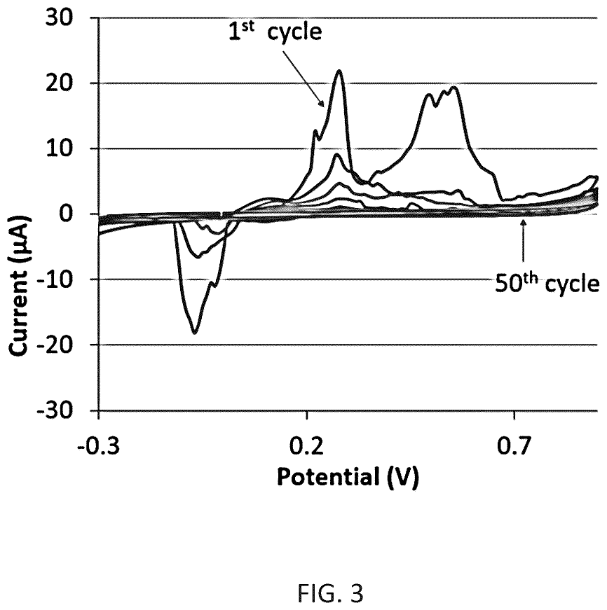

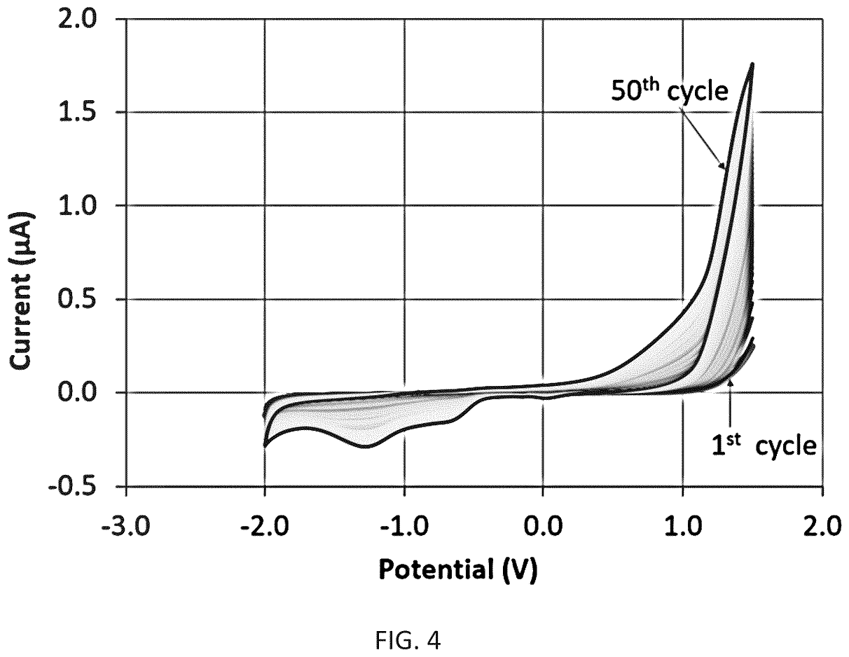

A cyclic voltammogram may be obtained during the cleaning process that can provide valuable information about the electrochemical behavior of the electrode and the efficiency of the cleaning process, examples of which are shown in FIGS. 3 and 4. The redox peaks observed in the voltammogram may help identify the species involved in the cleaning reactions and provide insights into the cleaning mechanism.

Selectivity and sensitivity of screen-printed electrodes may be improved by preparing the surface of the electrodes prior to functionalization using an electrolytic cleaning process using first an acid-etching solution, followed by a base-mediated neutralization step. These processes help to ensure that the surface is homogeneous before undergoing the chemical functionalization process. In a first step, the sensor is immersed in an acid bath having a pH of 20 about 1.0 to 3.0 and a voltage cycle between −0.3 V to +0.9 V is applied to the biosensor electrodes. In a subsequent step, the sensor is immersed in a basic bath having a pH of about 13.0 to 14.0 and a voltage cycle between −2.0 V to +1.5 V is applied to the biosensor electrodes. In doing so, the surface of the electrodes may be prepared for the additional manufacturing steps. The low pH mode with voltage cycling is important to oxidize organic contaminants on the electrode surface and expose the sp² carbon, whereas the high pH mode with voltage cycling serves to neutralize and remove contaminants from the surface of the electrodes.

The low and high pH voltage cycling both cycle between a negative voltage at a minimum value and a positive voltage at a maximum value to allow both reduction and oxidation occur in the solution. The voltage level applied, whether negative or positive, and whether in the low or high pH solutions, should be small enough to avoid damaging the silver electrode or the carbon surface. For example, the carbon surface may separate from the printed silver electrodes if the voltage level is too strong. In the low pH solution, the acidic pH may be between 1.0 to 3.0, the maximum voltage is between 0.8 V and 1.0 V, and the minimum voltage is between −0.4 V and −0.2 V. In the high pH solution, the basic pH may be between 13.0 and 14.0, the minimum voltage is between −2.1 V and −1.9 V, and the maximum voltage is between 1.4 V and 1.6 V.

In using an electrochemical grafting technique for functionalizing the surface, more continuous surface coverage is possible than common non-covalent approaches such as using pi-pi stacking to functionalize the surface, leading to better surface coverage, and stronger bonding to the biorecognition elements generating a more robust sensing surface.

Referring to FIG. 3, an example of a cyclic voltammetry analysis of a screen-printed carbon electrode cleaning process in an acidic solution is shown. The electrode was subjected to 50 consecutive scans where the potential is cycled between −0.3 V and +0.9 V. The scan rate was set at 500 m V/s, and the H₂SO₄ concentration was 0.4 M. The cyclic voltammogram depicts the current response as a function of the applied potential and is indicative of the cleaning and stability of the screen-printed carbon electrode after repeated scans in the acidic solution.

Referring to FIG. 4, an example of a cyclic voltammetry analysis of screen-printed carbon electrode cleaning process in a basic solution where the potential is cycled between −2.0 V to +1.5 V is shown in FIG. 4. The electrode was subjected to 50 consecutive scans. The scan rate was set at 500 mV/s, and the NaOH concentration was 0.4 M. The cyclic voltammogram depicts the current response as a function of the applied potential and is indicative of the cleaning and stability of the screenprinted carbon electrode after repeated scans in the basic solution.

A second function of the cleaning steps involves increasing the surface roughness of the electrode allowing the functionalization to occur on an effectively larger surface. Both of these features combine to enhance the reliability of signal generation when applied to the biosensor, allowing for repeatable performance in the detection of analytes.

To perform the diagnostic test, a detector may be used to transduce the binding event into a usable signal, which in this case is intended for use in electrochemical measurements. The selection of the appropriate electrochemical technique may be determined empirically but may be reliant on how binding to the surface changes electrical characteristics of the surface/interface on completion of the binding event. In one example, the sensor may be used in electrochemical impedance spectroscopy (EIS); a technique that is suitable for use with screen printed electrochemical sensors. The reason for selecting this technique is that it depends on the nature and chemical properties of the interface between the electrode surface and the electrolyte solution which means that any change at the surface will affect parameters such as the capacitance of the electrical double layer formed at the surface of the electrode, or a change in the charge transfer resistance relating to a redox couple selected to amplify the electrochemical impacts of binding. The species chosen may not otherwise interfere with the electrode surface and may be relatively inert and have predictable redox chemistry. Suitable candidates for the redox couple may include ferric/ferrocyanide solution which is commonly used in EIS for biosensing applications.

In electrochemical impedance detection, beneficial results are generally achieved by covering the surface of an electrochemical biosensor as thoroughly as possible which serves two overall purposes: to maximize the number of available active sites for binding to the analyte to occur, and to minimize the amount of surface left uncovered to allow for non-specific binding to either the analyte, or other elements present in the biological samples under test. To achieve this goal, the proposed approach involves a 3-fold strategy involving acidic and basic cleaning of the surface under applied potential, and then electrografting of the surface with a covalently bonded linker molecule, whose purpose is to provide a chemical handle that can then be bonded to any molecule, nanoparticle or microparticle that would provide an appropriately structured site for selective binding to the analyte of interest (the biological recognition element such as antibodies, aptamers, enzymes, or polypeptide molecules or fragments).

The method of manufacturing the proposed sensors is fundamentally flexible and while the discussion below is in the context of sensors used to detect SARS-COV-2 in saliva, the surface may be tailored to detect other viruses, such as known viruses (e.g., SARS-COV-1, MERS, HIV, Zika), or future viruses that have not yet evolved or presented.

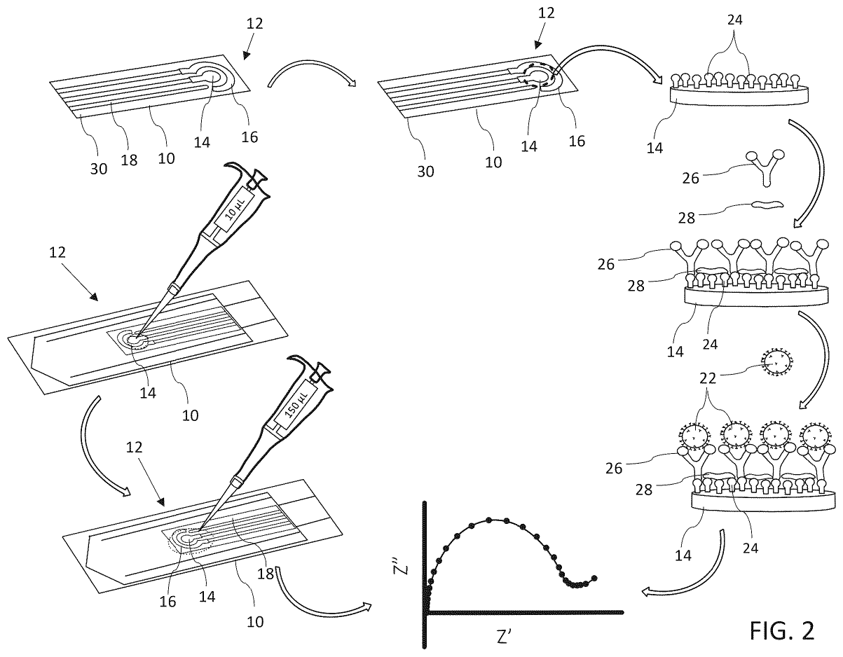

Generally, a screen-printed electrochemical sensor comprises several electrodes, such as a working electrode, a counter electrode, and a reference electrode that work together with a potentiostat to apply an electrical signal through an electrochemical cell containing electrolyte solution. The use of three or more electrodes may reduce the voltage drop in the electrochemical cell and improve the accuracy of electrochemical detection signal. The device architecture may include a sensing region 32 that includes working electrode 14, counter electrode 16, and reference electrode 18, and is designed to receive a test sample that is to be tested for the presence of an analyte of interest and a conductive fluid that places electrode 14, 16, 18 in electrical communication to test for the presence of any analyte that may be bound to the functionalized surfaces as shown in FIG. 2. A test signal may be applied to sensing region 32 using a signal generator (not shown) that applies an AC voltage that may have a variable frequency. The voltage difference is applied between working electrode 14 and counter electrode 16, while reference electrode 18 provide a reference for the voltage difference between electrodes 14 and 16.

In one example, Melinex® ST505 (source: DuPont) was used as a substrate to print three-electrode electrochemical biosensor device. The substrate consists of 500 μm thick film layer of PET-adhesive-PET. Silver ink was used to print electrical tracks and the reference electrode (thickness 7±1 μm), while the working and counter electrode (thickness 20±2 μm) were printed with carbon ink. A UV curable dielectric and varnish material (Fujifilm) was printed to the exposed silver tracks preventing it from contact with electrolyte solution. Each sheet of printed circuit consists of 120 sensors.

An example of a production process is shown in FIG. 1, starting with a bottom PET layer 40, to which an adhesive layer 42 and a top PET layer 44 were added to form substrate 30. Silver ink was then printed on the substrate and allowed to cure at about 125° C. for about 10 minutes to form electrical tracks 34. Carbon ink was then printed on the substrate and allowed to cure at about 125° C. for about 10 minutes to form working and counter electrodes 14 and 16. Two coats of dielectric ink were applied with each coat UV cured. A transparent varnish coat was then applied and UV cured.

In general, the substrate is selected for its stability at high temperatures. Preferably the substate should be able to withstand temperatures of between 100-150° C. for over 10 minutes of repeated exposure. This allows the inks to be cured at higher temperatures and for longer periods of time. In addition, the substrate is selected to have a sufficiently high dielectric constant to prevent shorting between electrodes or coated with a suitable dielectric material prior to printing the electrodes. In some cases, substrate 30 may be subjected to four or more heating cycles throughout the manufacturing process. A suitable substrate 30 may include one or more polymeric layers, such as PET as discussed above, that are adhered together and that are stable to the expected temperatures. In some examples, there may be 2, 3, or more layers, which may improve the structural stability of substrate 30.

The metal ink, such as silver ink, is selected due to its good conductivity, good resistance to organic and inorganic solvent and excellent adhesion to the surface and is cured at 125° C. for about 10 minutes, which results in stable and highly conductive silver ink tracks. In some examples, the sensor may be cured after each electrode is printed, or after more than one electrode is printed. The curing temperature may be about 100-150° C. The carbon ink, which may be any of those discussed above, is also cured such that solvent gets removed. A low porosity dielectric coating and transparent varnish print was UV cured to achieve excellent adhesion of the coating to the surface.

Once the substrate is prepared, the carbon working electrode surfaces may be functionalized using a linking molecule through diazotization reaction, which is then chemically converted to possess the right terminal group such that it can be bonded to biorecognition elements such as antibodies, aptamers, enzymes, or polypeptide molecules or fragments. In one example, aryldiazonium salts prepared from aminobenzoic acid are chosen that generate good surface coverage and provide the carboxylic acid group which is readily converted to N-Hydroxysuccinimide ester for subsequent reaction to primary amines present on the biomolecules which form the biological recognition elements for the sensors described. These biorecognition elements may then bind to, or otherwise react with, biological analytes of interest such as viruses, biomarkers, hormones, or bacterial debris. In using an electrochemical grafting technique for functionalizing the linker group on the surface, more continuous surface coverage is possible than common non-covalent approaches such as using pi-pi stacking to functionalize the surface, leading to better surface coverage, and stronger bonding to the biorecognition elements generating a more robust sensing surface.

An antibody or biorecognition element may be incubated on the functionalized working carbon electrode and stored in an airtight container at 4° C. fridge for 24 hours. The 24 hours incubation of the antibody ensures formation of a strong chemical bond between the antibody and the linker and generate a homogenously covered sensor surface, resulting in a reproducible sensor production.

To reduce a non-specific binding of analyte, the sensors functionalized with antibody should be incubated with a blocking agent in order to passivate the exposed surfaces of the sensor.

The combination of these processes may be used to achieve a reproducible and commercially viable production of electrochemical impedance spectroscopy-based biosensor. It has been found that the tests performed on the analyte in biological matrix in the presence of a redox couple improves signal strength.

Referring to FIG. 2, an example of a process by which a sensor is manufactured and used is shown, starting with a bare screen-printed carbon electrode (SPCE). Working electrode 14 is smudged then reacted with a linking molecule 24, biological recognition elements 26, and blocking agent 28 conjugation suitable for conjugation with a target biomolecule, such as a virus or bacteria. In one example, a 500 μm thick PET-adhesive-PET substrate 30 was used to print a three-electrode electrochemical biosensor device. The PET-adhesive-PET substrate 30 consisted of two layers of 185 μm thick ST505 PET film and a 130 μm thick adhesive layer. The PET-adhesive-PET substrates displayed higher resistance to repeated cycle of high temperature (125° C.), exposure to print metals and carbon inks, and were able to remain stable for organic and inorganic solvent treatment and were found to have a high and low pH resistance. The biosensor manufactured using this approach was found to be reproducible, with adequate levels of sensitivity, and stability. A dielectric layer 38 of the black dielectric ink and a transparent varnish material were applied and cured with repeated cycle of UV exposure. These layers were found to be biocompatible and did not leak, release toxic molecules, or degrade during electrochemical impedance spectroscopy detection. The application of double dielectric layer and a transparent varnish layer was found to be stable towards water and alcohol treatment.

Referring to FIG. 2, sensor 10 may be used to test an analyte by applying a test sample, for example a 10 μL volume, to working electrode 14 and allowed to bind with any analyte in the sample. Preferably, the test sample is localized on working electrode 14 to maximize exposure of the functionalized surface to the analyte. Once sufficient time has passed to allow the analyte to bind to working electrode 14, a conductive fluid, for example in a volume of 150 μL, is applied to sensing region 32 such that electrodes 14, 16, and 18 are in electrical communication. A voltage signal, which may have a variable voltage and/or frequency, is applied between electrodes 14 and 16, while electrode 18 is used as a reference. Referring to FIG. 1, when packed in a packaged sensor 50, an output signal may be measured using a detection circuit 50.

In this patent document, the word “comprising” is used in its non-limiting sense to mean that items following the word are included, but items not specifically mentioned are not excluded. A reference to an element by the indefinite article “a” does not exclude the possibility that more than one of the elements is present, unless the context requires that there be one and only one of the elements.

The scope of the following claims should not be limited by the preferred embodiments set forth in the examples above and in the drawings, but should be given the broadest interpretation consistent with the description as a whole.

1. A method of manufacturing a biosensor, comprising:
printing electrodes on a substrate using metallic ink;
printing a carbon surface using carbon-containing ink, the carbon surface being in electrical communication with the electrodes;
immersing the substrate in an acid bath having a pH of 3.0 or less and applying a first voltage cycle to the biosensor electrodes; and
immersing the substrate in a basic bath having a pH of 13.0 or more and applying a second voltage cycle;
wherein each of the first voltage cycle and the second voltage cycle comprise a minimum voltage that is less than 0 V and a maximum voltage that is greater than 0 V, the minimum voltage and the maximum voltage being selected to avoid damaging the electrodes and the carbon surface across a plurality of first voltage cycles and a plurality of second voltage cycles.

2. The method of claim 1, wherein the acidic pH is between 1.0 to 3.0, the maximum voltage is between 0.8 V and 1.0 V, and the minimum voltage is between −0.4 V and −0.2 V.

3. The method of claim 1, wherein the basic pH is between 13.0 and 14.0, the minimum voltage is between −2.1 V and −1.9 V, and the maximum voltage is between 1.4 V and 1.6 V.

4. The method of claim 1, wherein the first voltage cycle is applied 50 times or more.

5. The method of claim 1, wherein the second voltage cycle is applied 50 times or more.

6. The method of claim 1, wherein the electrodes and the substrate are cured by heating to a temperature of between 100-150° C. for 10 minutes or more.
